(19) United States
(12) Patent Application Publication
(10) Pub. No.: US 2010/0075499 A1
(43) Pub. Date: Mar. 25, 2010

(54) METHOD AND APPARATUS FOR METAL SILICIDE FORMATION

(76) Inventor: CHRISTOPHER S. OLSEN, Fremont, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/233,858

(22) Filed: Sep. 19, 2008

(51) Int. Cl. H01L 21/44

(52) U.S. Cl. 438/682; 257/E21.476

(57) ABSTRACT

Embodiments described herein include methods of forming metal silicide layers using a diffusionless annealing process. In one embodiment a method for forming a metal silicide material on a substrate is provided. The method comprises depositing a metal material over a silicon containing surface of a substrate, depositing a metal nitride material over the metal material, depositing a metallic contact material over the metal nitride material, and exposing the substrate to a diffusionless annealing process to form a metal silicide material. The short time-frame of the diffusionless annealing process reduces the time for the diffusion of nitrogen to the silicon containing interface to form silicon nitride thus minimizing the interfacial resistance.

### FIELD

Embodiments of the invention generally relate to the fabrication of semiconductor and other electronic devices and to methods for forming metal silicide materials on substrates.

### BACKGROUND

Integrated circuits are composed of many, e.g., millions, of devices such as transistors, capacitors, and resistors. Transistors, such as field effect transistors, typically include a source, a drain, and a gate stack. The gate stack typically includes a substrate, such as a silicon substrate, a gate dielectric, such as silicon dioxide (SiO₂) on the substrate, and a gate electrode, such as polycrystalline silicon, on the gate dielectric.

Integrated circuit device geometries have dramatically decreased in size since such devices were first introduced several decades ago and are continually decreasing in size today. Metal gates made of tungsten are becoming important because of the resistance requirements of theses smaller devices. Tungsten is a desirable material because it is widely available and has a lower resistivity and lower contact resistance compared to other conductive materials.

One drawback to using tungsten in a metal gate, however, is that the barrier layer is typically required between the silicon and the tungsten to prevent the formation of tungsten silicide. Tungsten silicide has a higher resistivity relative to tungsten and thus increases the overall resistance of the gate. Barrier layers such as metal nitrides have been used but due to the reaction of the metal nitride layer with the silicon gate, an additional metal layer is placed between the metal nitride layer and the silicon gate. The metal layer reacts with the silicon gate to form metal silicide. However, nitrogen from the metal nitride layer still reacts with the silicon gate to form silicon nitride which is a dielectric and increases the overall interfacial resistance of the gate stack.

Therefore, there is a need, for new methods for forming titanium suicide layers which provide reduced interfacial resistance in a gate stack.

### SUMMARY

Embodiments described herein include methods of forming metal silicide layers using a diffusionless annealing process. The short time-frame of the diffusionless annealing process reduces the time for the diffusion of nitrogen to the silicon containing interface to form silicon nitride thus minimizing the interfacial resistance. The short time frame also produces an extremely smooth silicide layer by minimizing all diffusion processes including the diffusion of reactants down grain.

In one embodiment a method for forming a metal silicide material on a substrate is provided. The method comprises depositing a metal material over a silicon containing surface of a substrate, depositing a metal nitride material over the metal material, depositing a metallic contact material over the metal nitride material, and exposing the substrate to a diffusionless annealing process to form a metal silicide material.

In another embodiment a method for forming a metal silicide material over a substrate is provided. The method comprises depositing a titanium material over a silicon containing surface of a substrate, depositing a titanium nitride material over the metal material, depositing a tungsten contact material over the titanium nitride material, and exposing the substrate to a diffusionless annealing process to form a titanium silicide material.

In yet another embodiment a method for forming a metal silicide material over a substrate is provided. The method comprises forming a gate stack electrode and annealing the gate stack electrode with a diffusionless annealing process to form a metal silicide layer. The gate stack electrode is formed by depositing a poly-silicon layer over the substrate, depositing a first metal layer over the substrate, depositing a metal nitride material over the substrate, and depositing a second metal material over the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a schematic top view of an integrated multi-chamber apparatus according to embodiments described herein;

FIG. 2 illustrates a process sequence for the formation of metal silicide material using a diffusionless annealing process according to one embodiment described herein;

FIG. 3 illustrates a process sequence for the for the formation of metal silicide material using a diffusionless annealing process according to another embodiment described herein;

FIG. 4 illustrates a process sequence for the for the formation of metal silicide material using a diffusionless annealing process according to yet another embodiment described herein; and

FIG. 5 shows a cross-sectional view of an exemplary gate oxide device utilizing a metal silicide material formed according to embodiments described herein.

To facilitate understanding, identical reference numerals have been used, where possible, to designate identical elements that are common to the figures. It is contemplated that elements disclosed in one embodiment may be beneficially utilized on other embodiment without specific recitation.

### DETAILED DESCRIPTION

A titanium silicide layer (TiₓSi_{y}) having a thickness less than 50 angstroms, such as about 30 angstroms or less, is formed using embodiments of a diffusionless annealing process described herein. The short time-frame of the diffusionless annealing process reduces the time for the diffusion of nitrogen to the silicon containing interface to form silicon nitride thus minimizing the interfacial resistance. The short time frame also produces an extremely smooth silicide layer by minimizing all diffusion processes including the diffusion of reactants down poly-Si grain. The titanium silicide layer has a resistivity of about 100 μohms-cm or less, and provides excellent resistance properties for various device applications, such as an electrode in either DRAM or capacitors, for example, without significantly increasing device resistance.

Diffusionless annealing methods or processes refer to those annealing processes that substantially do not diffuse dopants into surrounding layers, but keep the dopants in the intended parts of the semiconductor layer. Diffusionless annealing processes may have a short dwell time, for example, less than 10 milliseconds, which minimizes the diffusion of the dopants into surrounding layers (in some cases less than 2.5 nm diffusion). Diffusionless annealing processes may include laser annealing processes, such as millisecond annealing processes, nanosecond annealing processes, and microsecond annealing processes and flash lamp annealing processes including xenon flash lamp annealing processes.

Laser annealing methods or processces refer to those annealing processes that have been used to anneal the surface(s) of a substrate. In general, these processes deliver a constant energy flux to a small region on the surface of the substrate while the substrate is translated, or scanned, relative to the energy delivered to the small region. For laser annealing processes performed on a silicon containing substrate, the wavelength of the radiation is typically less than about 800 nm, and can be delivered at deep ultraviolet (UV), infrared (IR) or other desirable wavelengths. In one embodiment, the energy source may be an intense light source, such as a laser, that is adapted to deliver radiation at a wavelength between about 500 nm and about 11 micrometers. In most embodiments, the anneal process generally takes place on a given region of the substrate for a relatively short time, such as on the order of about one second or less. In one embodiment, the laser annealing process raises the substrate temperature to between about 1150-1350° C. for only about one second to remove damage in the substrate and achieve a desired dopant distribution.

Laser annealing methods or processes include pulsed laser annealing processes. Pulsed laser annealing processes may be used to anneal finite regions on the surface of the substrate to provide a well defined annealed and/or re-melted regions on the surface of the substrate. In general, during a pulsed laser anneal processes various regions on the surface of the substrate are exposed to a desired amount of energy delivered from the laser to cause the preferential heating of desired regions of the substrate. Pulsed laser anneal methods and processes have an advantage over other processes that sweep the laser energy across the surface of the substrate, since the need to tightly control the overlap between adjacently scanned regions to assure uniform annealing across the desired regions of the substrate is not an issue, since the overlap of the exposed regions of the substrate is typically limited to the unused space between die, or “kerf” lines.

Flash lamp annealing methods and processes may be used to generate visible light energy for pulsing onto the substrate. In one aspect, a pulse of energy from the energy source is tailored so that the amount of energy delivered to the anneal region and/or the amount of energy delivered over the period of the pulse is optimized to perform targeted annealing of desired areas. In one aspect, the wavelength of a laser is tuned so that a significant portion of the radiation is absorbed by a silicon layer disposed on the substrate.

In one aspect, a metal silicide layer, such as a titanium silicide material, is formed on a substrate surface by exposing a silicon material and a titanium material to a diffusionless annealing process. The diffusionless annealing process is performed under process conditions such that nitrogen from a metal layer does not diffuse to a silicon containing interface to form silicon nitride. In one embodiment, the diffusionless annealing process forms the metal suicide layer at a temperature between about 800° C. and about 1300° C., such as between about 900° C. and about 1200° C., for example about 1000° C. In one embodiment, the diffusionless annealing process is performed for less than 10 milliseconds, such as less than 5 milliseconds, for example, less than 1 millisecond. In one embodiment, the diffusionless annealing process may be a laser annealing process involving the application of a power density from about 3×10⁴ W/cm² to about 1×10⁵ W/cm² for 0.25 to 1 millisecond dwell time. Laser scan rates may range in the 25 mm/sec to 250 mm/sec to achieve these millisecond dwell times.

A “substrate surface” as described herein, refers to any substrate surface upon which film processing is performed. For example, a substrate surface may include silicon, silicon oxide, doped silicon, germanium, gallium arsenide, glass, sapphire, and any other materials such as metals, metal alloys, and other conductive materials, depending on the application. A substrate surface may also include dielectric materials such as silicon dioxide and carbon dopes silicon oxides.

A processing system for depositing and forming material on a substrate may contain at least one deposition chamber and at least one annealing chamber. Generally, the system contains at least one physical vapor deposition chamber (PVD) and/or at least one diffusionless anneal chamber. Other chambers may include, for example, chemical vapor deposition (CVD) chambers, atomic layer deposition (ALD) chambers, and pre-clean chambers. In one embodiment, a metal material is deposited on a silicon containing material, an optional metal nitride barrier layer may be deposited, and a metallic contact material is deposited on the substrate. The substrate is exposed to at least one diffusionless annealing process prior to, during, and/or subsequently to any of the deposition processes to form a metal silicide layer. In another embodiment, a titanium material is deposited on a polysilicon material, an optional titanium nitride barrier layer may be deposited on the titanium material, and a tungsten contact material is deposited on the substrate. The substrate is exposed to at least one diffusionless annealing process prior to, during, and/or subsequently to any of the deposition processes to form a titanium silicide layer.

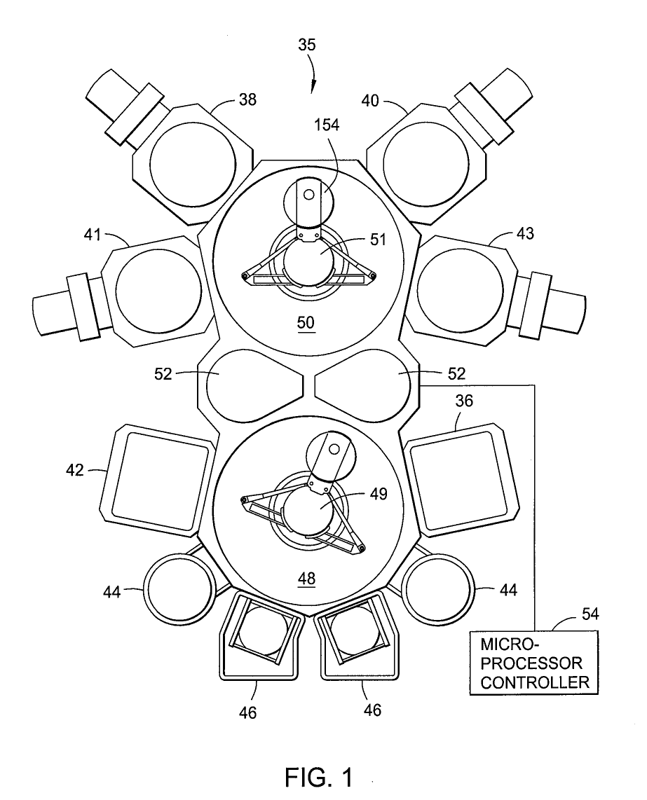

FIG. 1 shows an integrated multi-chamber substrate processing system suitable for performing at least one embodiment of the deposition and annealing processes described herein. The deposition and annealing processes may be performed in a multi-chamber processing system or cluster tool having at least one PVD chamber and at least one diffusionless annealing chamber disposed thereon. A processing platform that may be used during processes described herein is an ENDURA® processing platform commercially available from Applied Materials, Inc., located in Santa Clara, Calif. Other systems from other manufacturers may also be used to perform the processes described herein.

FIG. 1 is a schematic top view of one embodiment of a processing platform system 35 including two transfer chambers 48, 50, transfer robots 49, 51, disposed within transfer chambers 48, 50 respectfully, and a plurality of processing chambers 36, 38, 40, 41, 42 and 43, disposed on the two transfer chambers 48, 50. The first transfer chamber 48 and the second transfer chamber 50 are separated by pass-through chambers 52, which may comprise cool-down or pre-heating chambers. Pass-through chambers 52 also may be pumped down or ventilated during substrate handling when the first transfer chamber 48 and the second transfer chamber 50 operate at different pressures. For example, the first transfer chamber 48 may operate at a pressure within a range from about 100 milliTorr to about 5 Torr, such as about 400 milliTorr, and the second transfer chamber 50 may operate at a pressure within a range from about 1×10⁻⁵ Torr to about 1×10⁻⁸ Torr, such as about 1×10⁻⁷ Torr. Processing platform system 35 is automated by programming a microprocessor controller 54.

The first transfer chamber 48 is coupled with two degas chambers 44, two load lock chambers 46, a reactive preclean chamber 42 and chamber 36, such as an ALD processing chamber or a PVD chamber, and the pass-through chambers 52. The preclean chamber 42 may be a PreClean II chamber, commercially available from Applied Materials, Inc., of Santa Clara, Calif. Substrates (not shown) are loaded into processing platform system 35 through load-lock chambers 46. Thereafter, the substrates are sequentially degassed and cleaned in degas chambers 44 and the preclean chamber 42, respectively. The transfer robot 49 moves the substrate between the degas chambers 44 and the preclean chamber 42.

The second transfer chamber 50 is coupled to a cluster of processing chambers 38, 40, 41, and 43. In one example, chambers 38 and 40 may be PVD chambers for depositing materials, such as titanium, titanium nitride, or tungsten, as desired by the operator. In another example, the PVD chambers may be located on a separate platform such as the CENTURAE processing platform commercially available from Applied Materials, Inc., located in Santa Clara, Calif. In another example, chambers 38 and 40 may be CVD chambers for depositing materials, such as tungsten, as desired by the operator. An example of a suitable PVD chamber includes Self Ionized Plasma (SIP) and Advanced Low Pressure Source (ALPS) chambers, commercially available from Applied Materials, Inc., located in Santa Clara, Calif. Chambers 41 and 43 may be diffusionless annealing chambers that can anneal substrates at extremely high speeds. In another example, the diffusionless annealing chamber may be located on a separate platform such as the Vantage processing platform commercially available from Applied Materials, Inc., located in Santa Clara, Calif. An example of a diffusionless annealing chamber is a dynamic surface anneal (DSA) platform or a flash lamp annealing chamber commercially available from Applied Materials, Inc., Santa Clara, Calif. Alternatively, the chambers 41 and 43 may be low pressure CVD (LPCVD) deposition Polygen chambers capable of performing low pressure CVD deposition. The PVD processed substrates are moved from transfer chamber 48 into transfer chamber 50 via pass-through chambers 52. Thereafter, transfer robot 51 moves the substrates between one or more of the processing chambers 38, 40, 41, and 43 for material deposition and annealing as required for processing. In one embodiment

Additional annealing chamber such as Rapid Thermal Annealing (RTA) chambers and/or diffusionless annealing chambers may also be disposed on the first transfer chamber 48 of processing platform system 35 to provide post deposition annealing processes prior to substrate removal from processing platform system 35 or transfer to the second transfer chamber 50.

While not shown, a plurality of vacuum pumps is disposed in fluid communication with each transfer chamber and each of the processing chambers to independently regulate pressures in the respective chambers. The pumps may establish a vacuum gradient of increasing pressure across the apparatus from the load lock chamber to the processing chambers.

Alternatively, a plasma etch chamber or a decoupled plasma source chamber, such as a DPS® chamber available from Applied Materials, Inc., of Santa Clara, Calif., may be coupled to processing platform system 35 or in a separate processing system for etching the substrate surface to remove unreacted metal after PVD metal deposition and/or annealing of the deposited metal.

Referring to FIG. 1, the processing chambers 36, 38, 40, 41, 42 and 43, are each controlled by a microprocessor controller 54. The microprocessor controller 54 may be one of any form of general purpose computer processor (CPU) that can be used in an industrial setting for controlling processing chambers as well as sub-processors. The computer may use any suitable memory, such as random access memory, read only memory, floppy disk drive, hard drive, or any other form of digital storage, local or remote. Various support circuits may be coupled to the CPU for supporting the processor in a conventional manner. Software routines as required may be stored in the memory or executed by a second CPU that is remotely located.

Software routines are executed to initiate process recipes or sequences. The software routines, when executed, transform the general purpose computer into a specific process computer that controls the chamber operation so that a chamber process is performed. Alternatively, the software routines may be performed in hardware, as an application specific integrated circuit or other type of hardware implementation, or a combination of software and hardware.

### Metal Silicide Formation

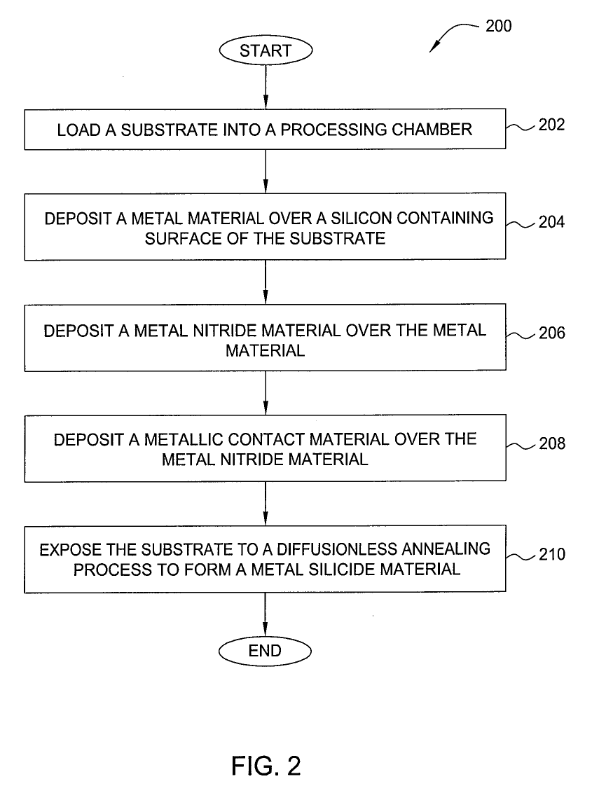

FIG. 2 illustrates a process sequence 200 for the formation of a metal material using a diffusionless annealing process according to one embodiment described herein. As shown in step 202, a substrate is provided to a process chamber, for example, a PVD process chamber 38. The process chamber conditions, such as the temperature and pressure are adjusted to enhance the deposition of a metal on the substrate.

In one embodiment, the substrate 154 may be a material such as crystalline silicon (e.g., Si<100> or Si<111>), silicon oxide, strained silicon, silicon germanium, doped or undoped polysilicon, doped or undoped silicon wafers and patterned or non-patterned wafers silicon on insulator (SOI), doped silicon, germanium, gallium arsenide, glass, and sapphire. The substrate 202 may have various dimensions, such as 200 mm or 300 mm diameter wafers, as well as, rectangular or square panes. Unless otherwise noted, embodiments and examples described herein are conducted on substrates with a 200 mm diameter or a 300 mm diameter. In one embodiment, the substrate may have a polysilicon gate electrode formed on a gate dielectric layer disposed over the substrate.

After step 202, a first metal layer which may function as a barrier layer is deposited over a silicon containing surface of the substrate in step 204. A first metal layer may be deposited on a substrate 154 disposed in chamber 38 as a barrier layer for a second metal layer may be deposited and annealed to form a metal silicide layer without breaking vacuum. The substrate 154 may include dielectric materials, such as silicon or silicon oxide materials, disposed thereon and may be patterned to define features into which metal films may be deposited or metal silicide films will be formed. The first metal layer may be deposited by a physical vapor deposition (PVD) technique, a CVD technique, or an atomic layer deposition technique. Suitable examples of metal layers include tungsten (W), titanium (Ti), hafnium (Hf), cobalt (Co), nickel (Ni), alloys thereof, or any combination thereof.

In a PVD process, the metal is deposited using the PVD chamber 38. The target of material, such as titanium, to be deposited is disposed in the upper portion of the chamber. A substrate 154 is provided to the chamber 38 and disposed on a substrate support pedestal. A processing gas is introduced into the chamber 38 at a flow rate of between about 5 sccm and about 30 sccm. The chamber pressure is maintained below about 5 milliTorr to promote deposition of conformal PVD metal layers. Preferably, a chamber pressure between about 0.2 milliTorr and about 2 milliTorr may be used during deposition. More preferably, a chamber pressure between about 0.2 milliTorr and about 1.0 milliTorr has been observed to be sufficient for sputtering titanium onto a substrate.

Plasma is generated by applying a negative voltage to the target between about 0 volts (V) and about −2,400 V. For example, negative voltage is applied to the target at between about 0 V and about −1,000 V to sputter material on a 200 mm substrate. A negative voltage between about 0 V and about −700 V may be applied to the substrate support pedestal to improve directionality of the sputtered material to the substrate surface. The substrate 154 is maintained at a temperature within a range from about 10° C. to about 500° C. during the deposition process.

An example of a metal deposition process includes introducing an inert gas, such as argon, into the chamber 38 at a flow rate between about 5 sccm and about 30 sccm, maintaining a chamber pressure between about 0.2 milliTorr and about 1.0 milliTorr, applying a negative bias of between about 0 volts and about 1,000 volts to the target to excite the gas into a plasma state, maintaining the substrate 154 at a temperature within a range from about 10° C. to about 500° C., preferably about 50° C. and about 200° C., and more preferably, between about 50° C. and about 100° C. during the sputtering process, and spacing the target between about 100 mm and about 300 mm from the substrate surface for a 200 mm substrate. Titanium may be deposited on the silicon material at a rate between about 300 Å/min and about 2,000 Å/min using this process. In one embodiment, the first metal layer may have a thickness between about 20 Å and about 100 Å. A collimator may be used with the process described herein with minimal detrimental affect on deposition rate.

While not shown, the first metal layer may be deposited by another method using the apparatus shown in FIG. 1. The titanium material may be deposited by a CVD technique, an ALD technique, an ionized magnetic plasma PVD (IMP-PVD) technique, a self-ionized plasma PVD (SIP-PVD) technique, an electroless deposition process, or combinations thereof. For example, the titanium material may be deposited by CVD in a CVD chamber, such as chamber 41 of processing platform system 35 as shown in FIG. 1, or by ALD in an ALD chamber or CVD chamber disposed at position 41, as shown in FIG. 1. The substrates may be transferred between various chambers within processing platform system 35 without breaking a vacuum or exposing the substrates to other external environmental conditions.

In step 206, prior to second metal deposition, such as tungsten, a layer of a barrier material, such as titanium or titanium nitride, may be deposited on the first metal layer. The layer of barrier material improves resistance to interlayer diffusion of the second metal layer into the underlying substrate or silicon material. Additionally, the layer of barrier material may improve interlayer adhesion between the first and second metal layers. Suitable barrier layer materials include titanium, titanium nitride, tantalum, tantalum nitride, tungsten, tungsten nitride, titanium-tungsten alloy, derivatives thereof, and combinations thereof. For example, tungsten nitride may be deposited on titanium nitride. The layer of barrier materials may be deposited by a CVD technique, an ALD technique, an IMP-PVD technique, a SIP-PVD technique, or combinations thereof.

In one embodiment, the metal nitride material is a titanium nitride material. In another embodiment, the metal nitride material is a tungsten nitride material. The metal nitride material may be formed by flowing a nitrogen gas into the processing chamber during the formation of the metal layer. In one embodiment, the processing gas may comprise between 10% and 30% nitrogen gas, for example, 20% nitrogen gas. In one embodiment, the nitrogen gas may be provided at an appropriate flow rate of between 5 sccm (standard cubic centimeters per minute) and 50 sccm, such as between 10 sccm and 30 sccm. The substrate is maintained at a temperature between about 50° C. and about 500° C. at a chamber pressure between about 1 torr and about 5 torr. In one embodiment, the metal nitride material may have a thickness between about 2 nm and about 10 nm.

The metal nitride layer may be deposited in the same chamber as the first metal layer. For example, if the first metal layer is a titanium layer deposited by a PVD process the metal nitride layer may be formed by flowing a nitrogen containing gas into the same chamber while depositing the titanium layer.

### Metallic Contact Material Deposition Processes

At step 208, a metallic contact material or second metal layer is deposited over the metal nitride material. In one embodiment, the metallic contact material comprises a tungsten material. Any metal deposition process such as conventional CVD, ALD, or PVD may be used to deposit the metallic contact material.

One exemplary process of depositing the metallic contact material includes physical vapor deposition. In the PVD process, the metal may be deposited using the PVD chamber 40. The target of material, such as tungsten, to be deposited is disposed in the upper portion of the chamber. A substrate 154 is provided to the chamber 40 and disposed on a substrate support pedestal. A processing gas is introduced into the chamber 40 at a flow rate of between about 5 sccm and about 30 sccm. The chamber pressure is maintained below about 5 milliTorr to promote deposition of conformal PVD metal layers. Preferably, a chamber pressure between about 0.2 milliTorr and about 2 milliTorr may be used during deposition. More preferably, a chamber pressure between about 0.2 milliTorr and about 1.0 milliTorr has been observed to be sufficient for sputtering tungsten onto a substrate.

Plasma is generated by applying a negative voltage to the target between about 0 volts (V) and about −2,400 V. For example, negative voltage is applied to the target at between about 0 V and about −1,000 V to sputter material on a 200 mm substrate. A negative voltage between about 0 V and about −700 V may be applied to the substrate support pedestal to improve directionality of the sputtered material to the substrate surface. The substrate 154 is maintained at a temperature within a range from about 10° C. to about 500° C. during the deposition process.

An example of a deposition process includes introducing an inert gas, such as argon, into the chamber 40 at a flow rate between about 5 sccm and about 30 sccm, maintaining a chamber pressure between about 0.2 milliTorr and about 1.0 milliTorr, applying a negative bias of between about 0 volts and about 1,000 volts to the target to excite the gas into a plasma state, maintaining the substrate 154 at a temperature within a range from about 10° C. to about 600° C., preferably about 50° C. and about 300° C., and more preferably, between about 50° C. and about 100° C. during the sputtering process, and spacing the target between about 100 mm and about 300 mm from the substrate surface for a 200 mm substrate. Tungsten may be deposited on the silicon material at a rate between about 300 Å/min and about 2,000 Å/min using this process. In one embodiment, the second metal layer may have a thickness between about 200 Å and about 1000 Å. A collimator may be used with the process described herein with minimal detrimental affect on deposition rate.

### Metal Silicide Formation Processes

At step 210, the substrate is exposed to a diffusionless annealing process to form a metal silicide material. The silicidation process converts a metal layer deposited over the silicon containing surface of a substrate in to a metal silicide layer. In one embodiment, the metal silicide material is a titanium silicide material. In one embodiment, the diffusionless anneal comprises a laser anneal such as a millisecond laser anneal. In another embodiment, the diffusionless anneal comprises a flash lamp anneal using, for example, a xenon flash lamp.

One exemplary process for forming the metal silicide layer involves exposing the substrate to a laser annealing process, such as a dynamic surface annealing (DSA) process. The laser annealing process may be performed by scanning the substrate with an energy beam that, for a short duration, heats an incremental portion of the substrate to temperature between about 800° C. and about 1300° C. The portion heated by the energy beam is maintained at the elevated temperature for less than 10 milliseconds, such as less than 1 millisecond. One suitable chamber for DSA process is the DSA platform, available from Applied Materials, Inc. It is contemplated that other DSA platforms, including those from other manufacturers, may be utilized to perform the laser annealing process.

The DSA process at step 210 may heat and activate the substrate at a predetermined high temperature. In one embodiment, the DSA process forms the metal silicidation layer at a temperature between about 800° C. and about 1300° C., such as between about 900° C. and about 1200° C., for example about 1000° C. The substrate is exposed to the laser for various time durations. In one embodiment, a DSA process is performed for less than 10 milliseconds, such as less than 5 milliseconds, for example, less than 1 millisecond. In one embodiment, the laser is pulsed for a time period between about 0.1 millisecond and about 1 millisecond. In one embodiment, the laser emits light with a wavelength selected at about 10.6 μm or about 0.88 μm, although other wavelengths may be utilized. The DSA process may be performed on a DSA platform, available from Applied Materials, Inc. One exemplary embodiment of a dynamic surface anneal process and platform is described in United States Patent Application Publication US 2007/0221640, titled APPARATUSES FOR THERMAL PROCESSING STRUCTURES FORMED ON A SUBSTRATE, to Jennings et al., which is herein incorporated by reference in its entirety.

Another exemplary process for forming the metal silicide layer involves exposing the substrate to a flash lamp RTP process, such as a xenon flash lamp RTP process. The flash RTP process involves: (1) rapid heating of the substrate to an intermediate temperature, and (2) while the substrate is heated to the intermediate temperature, very rapid heating of the substrate to a final temperature. The final temperature is higher than the intermediate temperature, and the time duration of the second step is less than the first time duration of the first step. By way of example, the first step of the flash RTP process may involve heating the substrate to an intermediate temperature range in a range of about 500° C. to about 900° C. for a time range of about 0.1 seconds to 10 seconds. The second step may involve heating the doped surface layer to a final temperature in a range of about 1000° C. to about 1300° C. and preferably in a range of about 0.1 milliseconds to 10 milliseconds and preferably for a time in a range of about 0.1 to about 2 milliseconds.

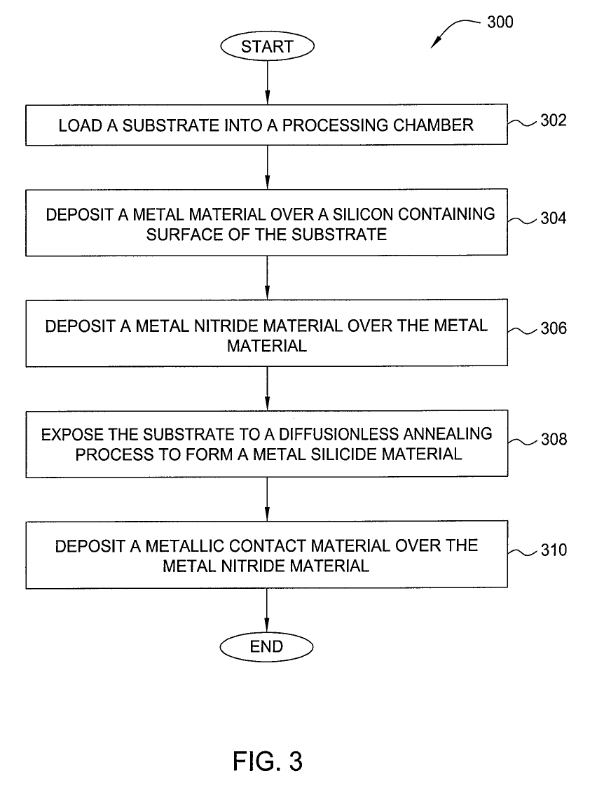

FIG. 3 illustrates a process sequence 300 for the formation of metal suicide material using a diffusionless anneal according to another embodiment described herein. The sequence includes loading a substrate into a processing chamber (step 302), depositing a metal layer over a silicon containing surface of the substrate (step 304), depositing a metal nitride material over the metal material (step 306), exposing the substrate to a diffusionless annealing process to form a metal silicide material (step 308), and depositing a metallic contact material over the metal nitride material (step 310).

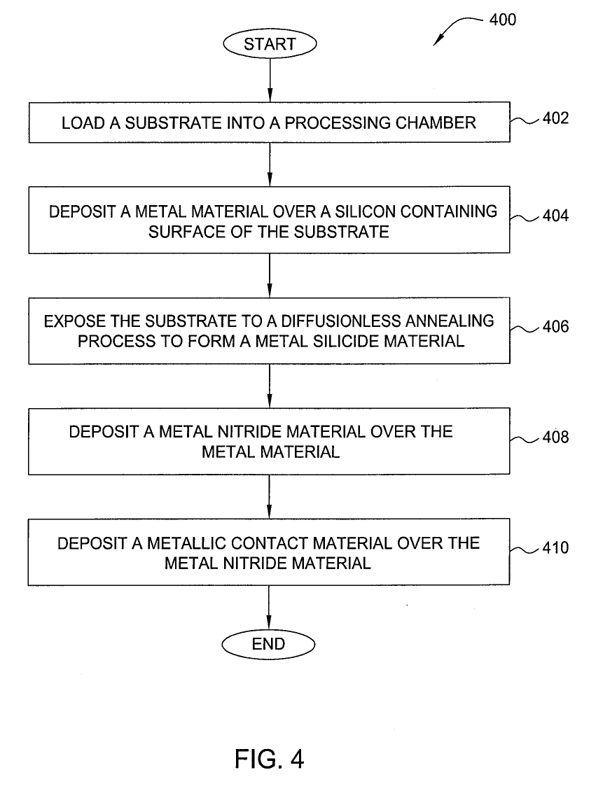

FIG. 4 illustrates a process sequence 400 for the formation of metal silicide material using a diffusionless annealing process according to yet another embodiment described herein. The sequence includes loading a substrate into a processing chamber (step 402), depositing a metal layer over a silicon containing surface of the substrate (step 404), exposing the substrate to a diffusionless annealing process to form a metal silicide material (step 406), depositing a metal nitride material over the metal material (step 408), and depositing a metallic contact material over the metal nitride material (step 410).

Optionally, prior to metal deposition on the substrate, the surface of the substrate may be cleaned to remove contaminants. The cleaning process may be performed by a wet etch process, such as exposure to a hydrofluoric acid solution, or by a plasma cleaning process, such as exposure to a plasma of an inert gas, a reducing gas, such as hydrogen or ammonia, or combinations thereof. The cleaning process may also be performed between processing steps to minimize contamination of the substrate surface during processing. The plasma clean process may be performed in the PreClean II processing chamber and the RPC⁺ processing chamber described herein, of which both are commercially available form Applied Materials, Inc., of Santa Clara Calif.

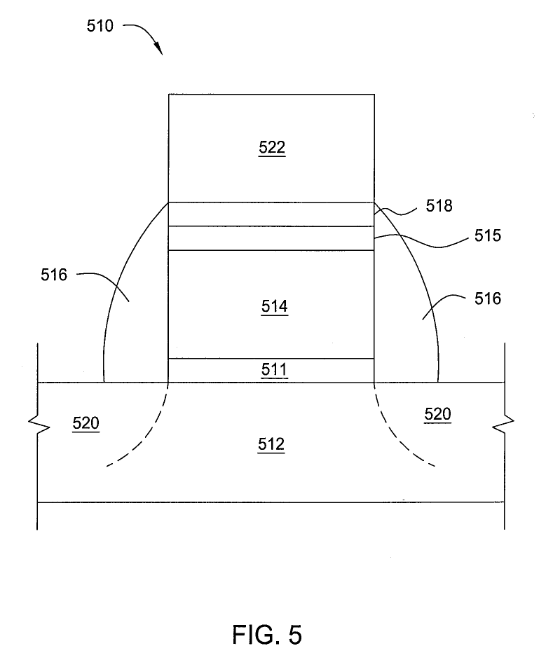

FIG. 5 shows a cross-sectional view of an exemplary gate oxide device utilizing a metal silicide material formed according to embodiments described herein. The device generally includes an exposed gate 510 surrounded by spacers 516 and silicon source/drain areas 520 formed within a substrate surface 512. The spacers 516 typically consist of an oxide, such as SiO₂.

The metal gate 510 includes an oxide layer 511, a polysilicon layer 514, a titanium silicide layer 515, a titanium nitride layer 518, and a tungsten layer 522. The titanium silicide layer 515 is formed using embodiments described above with reference to FIGS. 2-4. The oxide layer 511, such as a SiO₂ layer for example, separates the substrate 512 from the polysilicon layer 514. The oxide layer 511 and the polysilicon layer 514 are deposited using conventional deposition techniques.

### EXAMPLES

### Example 1

A titanium material is deposited over a polysilicon material disposed on a substrate, a titanium nitride material is deposited over the titanium material, and a tungsten material is deposited over the titanium nitride material. The substrate is treated with a diffusionless anneal to form a titanium disilicide (TiSi₂) between the polysilicon material and the titanium nitride material. An optional pre-clean process may be performed on the substrate prior to processing. The titanium material and the titanium nitride material may be deposited in a first processing chamber, the tungsten material may be deposited in a second processing chamber, and the titanium silicide material may be formed in a third processing chamber.

### Example 2

A titanium material is deposited over a polysilicon material disposed on a substrate, a titanium nitride material is deposited over the titanium material, a tungsten nitride material is deposited over the titanium nitride material, and a tungsten material is deposited over the tungsten nitride material. The substrate is treated with a diffusionless anneal to form a titanium disilicide (TiSi₂) between the polysilicon material and the titanium nitride material. An optional pre-clean process may be performed on the substrate prior to processing. The titanium material and the titanium nitride material may be deposited in a first processing chamber, the tungsten nitride and the tungsten material may be deposited in a second processing chamber, and the titanium silicide material may be formed in a third processing chamber.

Embodiments described herein include methods of forming metal silicide layers using a diffusionless anneal. Embodiments described herein further provide methods for millisecond annealing of tungsten-poly DRAM electrodes for reduced interfacial resistance. The short time-frame of the diffusionless anneal reduces the time for the diffusion of nitrogen to the silicon containing interface to form silicon nitride thus minimizing the interfacial resistance. The short time frame also produces an extremely smooth silicide layer by minimizing all diffusion processes including the diffusion of reactants down grain.

While the foregoing is directed to embodiments of the present invention, other and further embodiments of the invention may be devised without departing from the basic scope thereof, and the scope thereof is determined by the claims that follow.

1. A method for forming a metal silicide material on a substrate, comprising:
depositing a metal material over a silicon containing surface of a substrate;
depositing a metal nitride material over the metal material;
depositing a metallic contact material over the metal nitride material; and
exposing the substrate to a diffusionless annealing process to form a metal silicide material.

2.-3. (canceled)

4. The method of claim 1, wherein the diffusionless annealing process comprises a laser annealing process or a flash lamp annealing process.

5. The method of claim 1, wherein the metal silicide material is formed between the metal nitride material and the silicon containing surface.

6. The method of claim 1, wherein the diffusionless annealing process is performed using process conditions so that the metal nitride does not react with the silicon containing surface layer.

7. The method of claim 1, wherein exposing the substrate to a diffusionless annealing process comprises exposing the substrate to a temperature between about 900° C. and about 1100° C.

8. The method of claim 1, wherein the diffusionless annealing process is performed for a time period less than about 10 milliseconds.

9. The method of claim 1, wherein the metal material comprises cobalt, titanium, tantalum, tungsten, molybdenum, platinum, nickel, iron, niobium, palladium, and combinations thereof.

10. A method for forming a metal silicide material on a substrate, comprising:
depositing a titanium material over a silicon containing surface of a substrate;
depositing a titanium nitride material over the titanium material;
depositing a tungsten contact material over the titanium nitride material; and
exposing the substrate to a diffusionless annealing process to form a titanium silicide material.

11. The method of claim 10, further comprising depositing a tungsten nitride material in between the titanium nitride material and the tungsten contact material.

12. The method of claim 10, wherein the diffusionless annealing process comprises a laser annealing process or a flash lamp annealing process.

13. The method of claim 10, wherein the titanium silicide material is formed between the titanium nitride material and the silicon containing surface.

14. The method of claim 10, wherein the diffusionless annealing process is performed for a time period less than about 10 milliseconds.

15. A method for forming a metal silicide material on a substrate, comprising:
forming a gate electrode stack comprising:
depositing a poly-silicon layer over the substrate;
depositing a first metal layer over the substrate;
depositing a metal nitride layer over the substrate; and
depositing a second metal layer over the substrate; and
annealing the gate electrode stack with a diffusionless annealing process to form a metal silicide layer.

16. The method of claim 15, wherein the diffusionless annealing process is performed at process conditions such that the metal nitride layer does not react with the polysilicon layer.

17. The method of claim 15, wherein the annealing the gate electrode is performed after depositing a metal nitride layer over the substrate.

18. The method of claim 15, wherein the annealing the gate electrode is performed after depositing a second metal layer over the substrate.

19. The method of claim 15, wherein the annealing the gate electrode stack comprises performing a diffusionless annealing process for a time period less than 10 milliseconds.

20. The method of claim 15, wherein the first metal layer comprises titanium, the metal nitride layer comprises titanium nitride, the second metal layer comprises tungsten, and the metal silicide layer comprises titanium silicide.

21. The method of claim 1, wherein the metal material and the metal nitride material are deposited in a first processing chamber, the metallic contact material is deposited in a second processing chamber, and the diffusionless annealing process occurs in a third processing chamber.

22. The method of claim 10, wherein the titanium material is deposited to a thickness within a range from about 20 angstroms to about 100 angstroms.
